(19) United States
(12) Patent Application Publication
(10) Pub. No.: US 2024/0128185 A1
(43) Pub. Date: Apr. 18, 2024

(54) SEMICONDUCTOR DEVICE AND PRE-FORMING ADAPTOR THEREOF

(71) Applicant: PANJIT INTERNATIONAL INC., Kaohsiung (TW)

(72) Inventors: Chung Hsiung Ho, Kaohsiung (TW); Chi Hsueh Li, Kaohsiung (TW)

(21) Appl. No.: 18/079,076

(22) Filed: Dec. 12, 2022

(30) Foreign Application Priority Data
Oct. 12, 2022 (TW) 111138558

(51) Int. Cl. H01L 23/498; H01L 21/48; H01L 21/56; H01L 23/00; H01L 23/13; H01L 23/31

(52) U.S. Cl. CPC H01L 23/49861; H01L 21/4846; H01L 21/561; H01L 21/563; H01L 23/13; H01L 23/3121; H01L 24/16; H01L 24/29; H01L 24/32; H01L 24/73; H01L 24/81; H01L 24/92; H01L 24/97; H01L 2224/16225; H01L 2224/2919; H01L 2224/32225; H01L 2224/73204; H01L 2224/81815; H01L 2224/92125; H01L 2224/97; H01L 2924/0665

(57) ABSTRACT

A pre-forming adaptor for semiconductor packaging includes at least one lead frame and at least one packaging enclosure bonded with the at least one lead frame. Each of the lead frame and the packaging enclosure has a pre-forming shape provided according to a predetermined package outline of a semiconductor device.

### CROSS-REFERENCE TO RELATED APPLICATIONS

This application claims priority under 35 U.S.C. § 119(a) on Patent Application No(s). 111138558 filed in Taiwan, R.O.C. on Oct. 12, 2022, the entire contents of which are hereby incorporated by reference.

### BACKGROUND

### 1. Technical Field

This present disclosure relates to a semiconductor device, more particularly to a pre-forming adaptor for the semiconductor device.

### 2. Related Art

Semiconductor packaging involves the accommodation of a chip inside a packaging structure including pins and enclosure, and even the encapsulation of the chip with non-conductive material for moisture-proof in order to protect the chip from external moisture, dust, static electricity, and so on. The chip may be obtained by cutting a wafer to obtain a separate die having integrated circuit thereon. The enclosure of the packaging structure may be made of plastic, glass or ceramic.

In general, a semiconductor packaging process performed by an assembly house begins with the bonding of the chip with a lead frame, followed by the formation of the enclosure having an outline for a product according to, for example, the requirements of a design house (one of end customers for the assembly house). As to a conventional semiconductor packaging process, a metal sheet is attached to a temporary substrate, and the lead frame is formed by etching of the metal sheet. Then, the bonding of the chip with the lead frame and the formation of the enclosure for packaging are performed in sequence. The enclosure is usually formed by epoxy resin which encapsulates the chip and part of the lead frame.

However, since the products with various model numbers consisting of different specification features may use the same chip, the flexibility of the above-mentioned semiconductor packaging process is insufficient when there are many products with various model numbers. For example, a kind of chip is widely used in vehicle devices by the end customers, so that the assembly house sets up an assembly line dedicated to package said kind of chip inside a packaging structure suitable for vehicle devices. However, if the end customers develop a new product for mobile electronics and this product also uses said kind of chip, the assembly house will have to set up another assembly line dedicated for the new product, which results in high manufacturing cost.

### SUMMARY

According to one embodiment of the present disclosure, a pre-forming adaptor for semiconductor packaging includes at least one lead frame and at least one packaging enclosure bonded with the at least one lead frame. Each of the lead frame and the packaging enclosure has a pre-forming shape provided according to a predetermined package outline of a semiconductor device.

According to another embodiment of the present disclosure, a semiconductor device includes a pre-forming adaptor and a chip. The pre-forming adaptor includes a lead frame and a packaging enclosure bonded with the lead frame. Each of the lead frame and the packaging enclosure has a pre-forming shape provided according to a predetermined package outline of the semiconductor device. The chip is disposed to the pre-forming adaptor, and the chip is electrically connected to the lead frame.

### BRIEF DESCRIPTION OF THE DRAWINGS

FIG. 1 is a schematic view of a semiconductor device according to a first embodiment of the present disclosure;

FIG. 2 through FIG. 7 are schematic views showing a method of fabricating the semiconductor device in FIG. 1;

FIG. 8 is a schematic view of a semiconductor device according to a second embodiment of the present disclosure;

FIG. 9 through FIG. 14 are schematic views showing a method of fabricating the semiconductor device in FIG. 8;

FIG. 15 is a schematic view of a semiconductor device according to a third embodiment of the present disclosure;

FIG. 16 through FIG. 21 are schematic views showing a method of fabricating the semiconductor device in FIG. 15;

FIG. 22 is a schematic view of a semiconductor device according to a fourth embodiment of the present disclosure; and

FIG. 23 through FIG. 28 are schematic views showing a method of fabricating the semiconductor device in FIG. 22.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present disclosure. The following embodiments further illustrate various aspects of the present disclosure, but are not meant to limit the scope of the present disclosure.

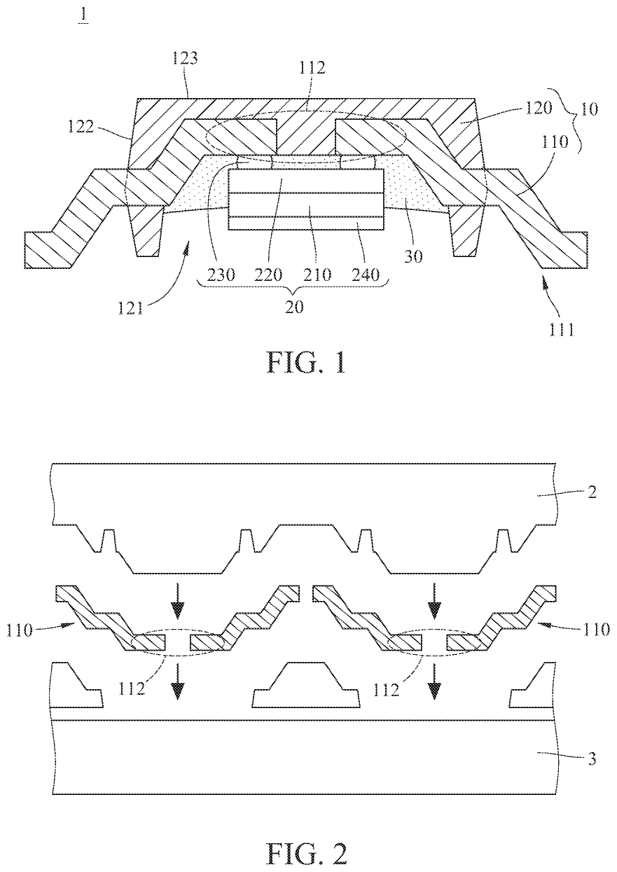

Please refer to FIG. 1 which is a schematic view of a semiconductor device according to a first embodiment of the present disclosure. In this embodiment, a semiconductor device 1 includes a pre-forming adaptor 10, a chip 20 and an under filler 30.

The pre-forming adaptor 10 includes a lead frame 110 and a packaging enclosure 120 bonded with the lead frame 110. Each of the lead frame 110 and the packaging enclosure 120 has a pre-forming shape provided according to a predetermined package outline of a semiconductor device 1. In detail, before the packaging of a chip into the pre-forming adaptor 10, the lead frame 110 and the packaging enclosure 120 have been pre-formed according to the actual external appearance of a product required by end customers. In this embodiment, the package outline of the semiconductor device 1 predetermined by end customers may include bent pins, so that the pre-forming shape of the lead frame 110 may include at least one bent portion 111. Furthermore, the package outline of the semiconductor device 1 predetermined by end customers may include the packaging enclosure 120 with specific overall thickness for accommodating the chip 20 and the under filler 30, so that the pre-forming shape of the packaging enclosure 120 may include a cavity 121 having sufficient amount of internal space for accommodating the chip 20. The cavity 121 may be referred as a chip accommodation cavity. A method of fabricating the pre-forming adaptor 10 will be further described hereafter.

The chip 20 is disposed to the pre-forming adaptor 10, and the chip 20 is electrically connected to the lead frame 110. In detail, the chip 20 may be a die or an electronic element fabricated by chip scale package (CSP). FIG. 1 exemplarily shows an electronic element fabricated by CSP as the chip 20, and said electronic element may include a semiconductor layer 210 (known as a die), a redistribution layer 220, one or more solder balls 230 and a protective layer 240. The semiconductor layer 210 is located between the redistribution layer 220 and the protective layer 240. The pre-forming shape of the lead frame 110 may include a soldering pattern 112 corresponding to electrical connection points of the chip 20. Specifically, in the case that the chip 20 is fabricated by CSP, the lead frame 110 is processed to have a specific shape according to the distribution of the solder balls 230 (that is, electrical connection points) of the chip 20, before the chip 20 is packaged into the pre-forming adaptor 10. The lead frame 110 extends through the packaging enclosure 120, and a part of the lead frame 110 is exposed in the cavity 121 to be the soldering pattern 112 corresponding to the solder balls 230. In this embodiment, The CSP may be accomplished by wafer level packaging. Also, solder balls are electrical connection points of the chip in this embodiment, while the electrical connection points may be multiple contact pads for wire bonding in some other embodiments.

The under filler 30 may be an epoxy resin accommodated in the cavity 121 of the packaging enclosure 120. The under filler 30 encapsulates the solder balls 230 (that is, electrical connection points) of the chip 20 and exposes at least part of the die (that is, the semiconductor layer 210). The under filler 30 is helpful to improve the mechanical strength of connection between the chip 20 and the lead frame 110 so as to ensure that the chip 20 can meet the requirement of mechanical shock resistance.

The following description is related to a method of fabricating the semiconductor device 1. FIG. 2 through FIG. 7 are schematic views showing a method of fabricating the semiconductor device in FIG. 1. First, the pre-forming adaptor 10 is provided by a pre-forming process.

The pre-forming process for the pre-forming adaptor 10 includes a step of providing multiple lead frames 110 having the pre-forming shape according to the package outline of the semiconductor device 1. As shown in FIG. 2, a metal structure, such as a metal sheet with holes, may be pre-cut into separate lead frames 110, and each of the lead frames 110 is bent to have a pre-forming shape with its end suitable as a pin. Moreover, the pre-forming shape of each lead frame 110 also includes a soldering pattern 112 corresponding to the distribution of solder balls on the chip, and the soldering pattern 112 may be formed by a stamping process or an etching process.

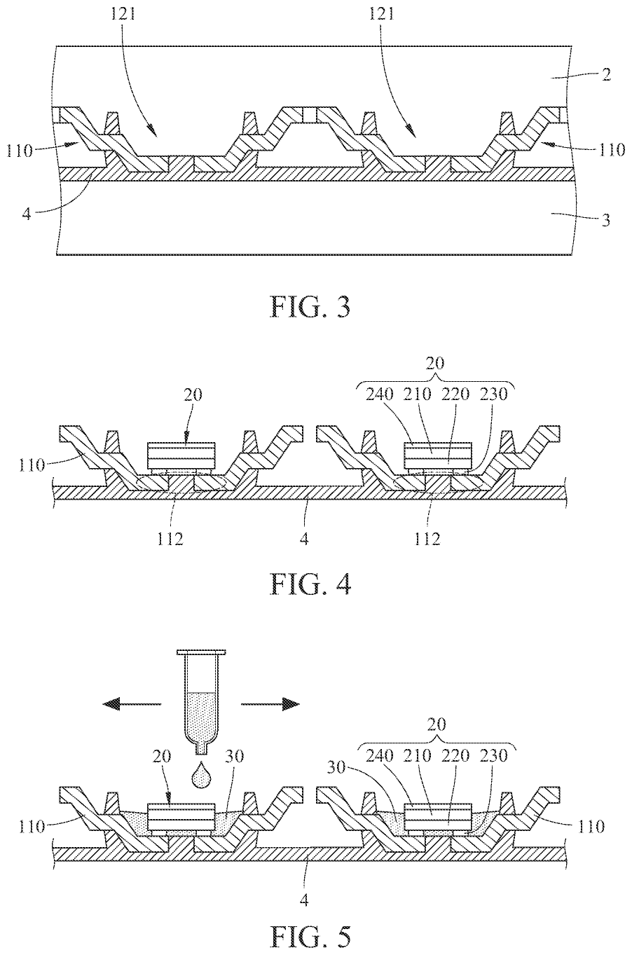

The pre-forming process for the pre-forming adaptor 10 further includes a step of forming multiple packaging enclosures 120 having the pre-forming shape on the lead frames 110 by injection molding. As shown in FIG. 2 and FIG. 3, the lead frames 110 are positioned between an upper mold 2 and a lower mold 3. The upper mold 2 and the lower mold 3 are in close contact with each other, and thermosetting dielectric material is injected into the molds to form an injection molded part 4 as single piece (that is, a one-pieced part). After the injection molding, the injection molded part 4 is demolded to obtain the pre-forming adaptors 10. The injection molded part 4 may be cut into separate packaging enclosures 120 in a subsequent step (as shown in FIG. 7), and the injection molded part 4 may include multiple cavities 121 for accommodating chips.

Next, multiple chips 20 are disposed in the pre-forming adaptors 10. As shown in FIG. 3 and FIG. 4, the chips 20 are disposed in respective cavities 121 after the pre-forming process. The solder balls 230 of each of the chips 20 may be bonded with the soldering pattern 112, so that the chip 20 is electrically connected to the lead frame 110. The attachment of the solder balls 230 to the soldering pattern 112 may be accomplished by reflow soldering.

As shown in FIG. 5, liquid under filler 30 is filled into the cavities 121 of the injection molded part 4. In one cavity 121, the under filler 30 cools down and solidifies so as to encapsulate the redistribution layer 220 and the solder balls 230 of the chip 20. The semiconductor layer 210 and the protective layer 240 of the chip 20 are not encapsulated by the under filler 30 so as to be exposed to outside. The exposed semiconductor layer 210 is helpful for heat dissipation.

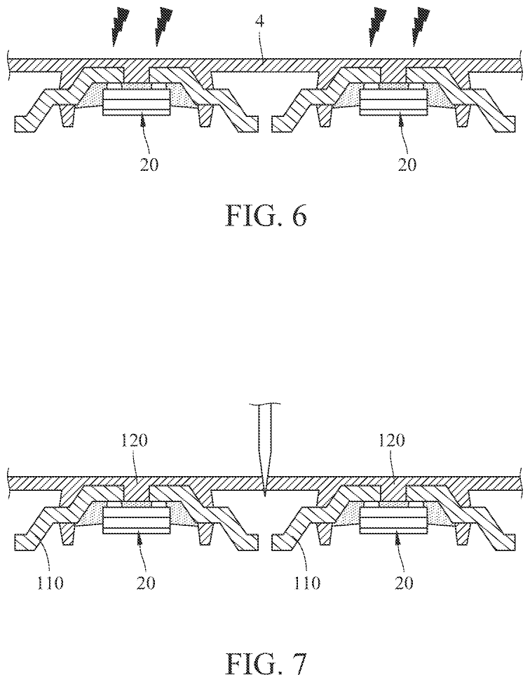

As shown in FIG. 6, a mark may be optionally formed on the injection molded part 4 or the protective layer 240 of the chip 20 by laser marking. The mark may represent the product information about the semiconductor device 1, such as a model number (or called product NO.). Also, the surface of the lead frame 110 may be optionally tinned to improve electrical conductivity, and the tinning process may be performed after the pre-forming process of the lead frame 110 or after the step of filling the under filler 30.

As shown in FIG. 7, the injection molded part 4 may be cut into separate packaging enclosures 120 by a cutting process. Each of the packaging enclosures 120 has one of the cavities 121, and the packaging enclosures 120 are bonded with respective lead frames 110. The semiconductor device 1 including the lead frame 110, the packaging enclosure 120 and the chip 20 can be fabricated by the method depicted in FIG. 2 through FIG. 7. Furthermore, during the cutting process, the injection molded part 4 is cut while the lead frames 110 are not cut, so that it is helpful to prevent metal burrs at the edge of the lead frame 110, and thus ensure that the lead frame 110 will not scratch other electronic components when the semiconductor device 1 is assembled with said other electronic components. The outer surface of the packaging enclosures 120 may have a gate trace due to injection molding.

FIG. 1 exemplarily shows that the chip 20 is packaged to obtain the semiconductor device 1 with specific model number, and the semiconductor device 1 is, for example but not limited to, applied to electronic devices such as servers, vehicle devices or high-end smartphones. The chip 20 may be applied to another semiconductor device with different model number from the semiconductor device 1. According to one implementation the present disclosure, when end customers require the semiconductor device 1 which has a first model number and includes the chip 20 packaged therein, the shape of the lead frame 110 and the packaging enclosure 120 can be determined according to the package outline of the first model number, and the lead frame 110 and the packaging enclosure 120 can be pre-formed before the packaging of the chip 20. When end customers require the semiconductor device which has a second model number different from the first model number and includes the chip 20 packaged therein, the lead frame and the packaging enclosure can be pre-formed according to the package outline of the second model number before the packaging of the chip 20.

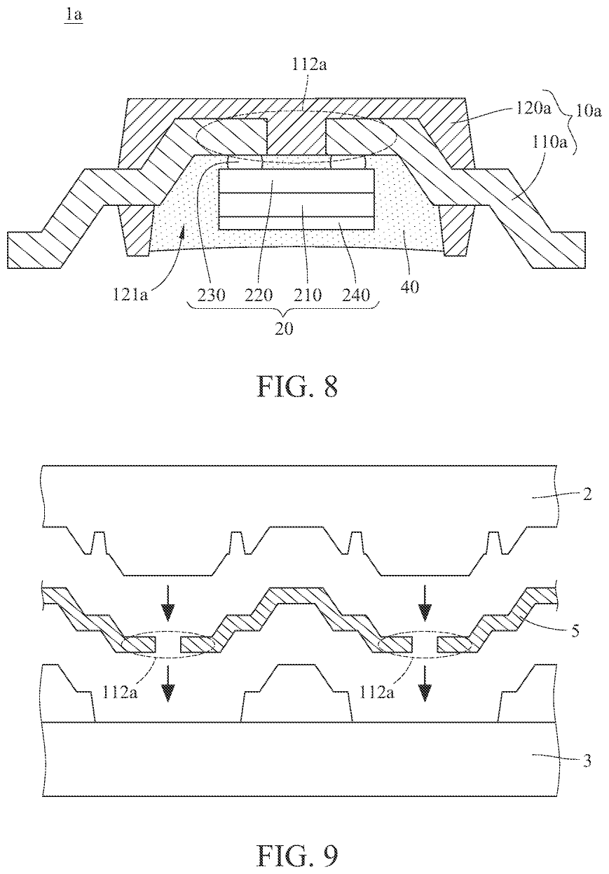

An example of a semiconductor device where the chip 20 is packaged can be referred to FIG. 8. FIG. 8 is a schematic view of a semiconductor device according to a second embodiment of the present disclosure. In this embodiment, a semiconductor device 1a includes a pre-forming adaptor 10a, a chip 20 and a dielectric material 40. The semiconductor device 1a is, for example but not limited to, applied to servers, vehicle devices or high-end smartphones. The semiconductor device 1a may have different package outline from the semiconductor device 1 in FIG. 1.

The pre-forming adaptor 10a includes a lead frame 110a and a packaging enclosure 120a bonded with the lead frame 110a. Each of the lead frame 110a and the packaging enclosure 120a has a pre-forming shape provided according to a predetermined package outline of a semiconductor device 1a. A method of fabricating the pre-forming adaptor 10a will be further described hereafter.

The chip 20 is disposed to the pre-forming adaptor 10a, and the chip 20 is electrically connected to the lead frame 110a. A configuration of the chip 20 can be referred to the corresponding element in the first embodiment, and any detail description will be omitted hereafter. The dielectric material 40 may be a polymer accommodated in a cavity 121a of the packaging enclosure 120a and encapsulate the chip 20. The dielectric material is helpful to improve electromagnetic compatibility (EMC) of the semiconductor device 1a.

FIG. 9 through FIG. 14 are schematic views showing a method of fabricating the semiconductor device in FIG. 8. First, the pre-forming adaptor 10 is provided by a pre-forming process.

The pre-forming process includes a step of providing multiple lead frames 110a having the pre-forming shape according to the package outline of the semiconductor device 1a. As shown in FIG. 9, a metal part 5 as single piece (that is, a one-pieced part) is bent to have a pre-forming shape. The metal part 5 may be cut into separate lead frames 110a with each having the pre-forming shape suitable as a pin in a subsequent step (as shown in FIG. 14), and the pre-forming shape of the metal part 5 may include multiple soldering patterns 112a corresponding to the distribution of solder balls on the chip.

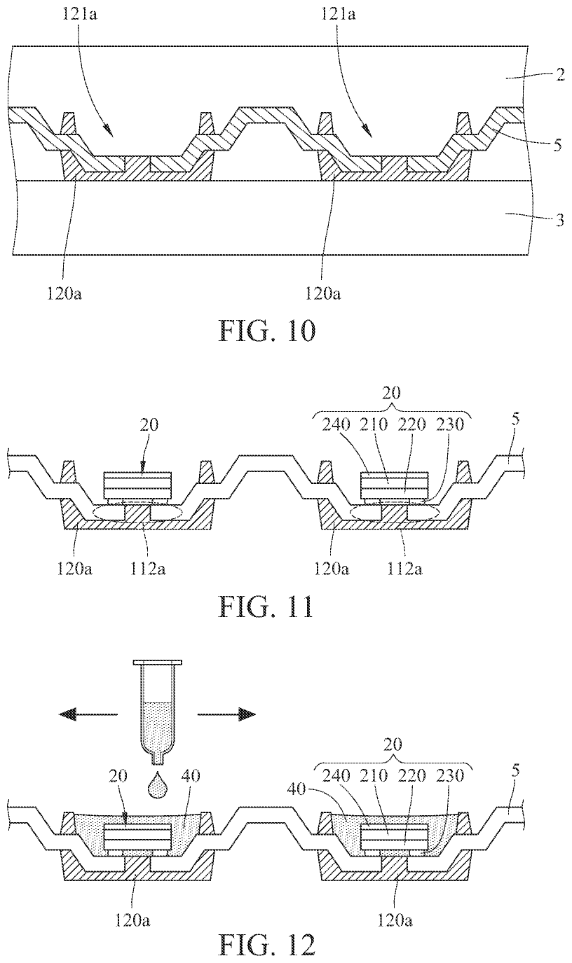

The pre-forming process further includes a step of forming multiple packaging enclosures 120a having the pre-forming shape on the metal part 5 by injection molding. As shown in FIG. 9 and FIG. 10, the metal part 5 is positioned between an upper mold 2 and a lower mold 3. The upper mold 2 and the lower mold 3 are in close contact with each other, and thermosetting dielectric material is injected into the molds to form separate packaging enclosures 120a. The outer surface of each of the packaging enclosures 120a may have a gate trace due to injection molding. After the injection molding, the packaging enclosures 120a are demolded to obtain the pre-forming adaptors 10a, and each of the packaging enclosures 120a includes a cavity 121a for accommodating the chip.

Next, multiple chips 20 are disposed in the pre-forming adaptors 10a. As shown in FIG. 11, the chips 20 are disposed in respective cavities 121a after the pre-forming process. The solder balls 230 of each of the chips 20 may be bonded with the soldering pattern 112a. The attachment of the solder balls 230 to the soldering pattern 112a may be accomplished by reflow soldering.

As shown in FIG. 12, liquid dielectric material 40 is filled into the cavity 121a of each packaging enclosure 120a. The dielectric material 40 solidifies so as to encapsulate the semiconductor layer 210, the redistribution layer 220 and the solder balls 230 of the chip 20.

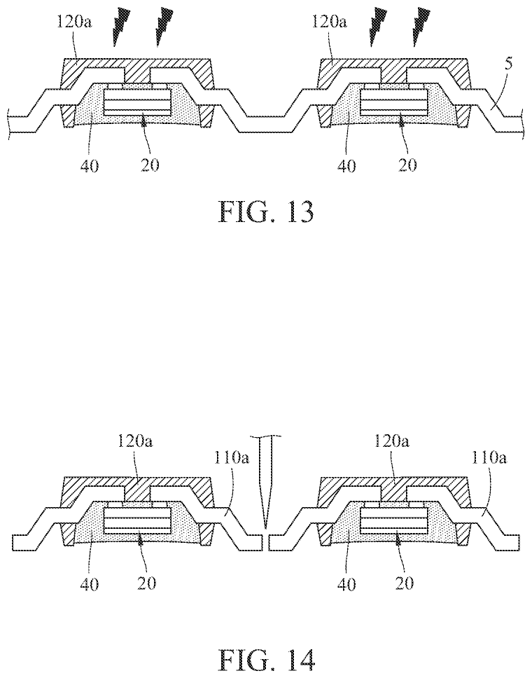

As shown in FIG. 13, a mark may be optionally formed on each packaging enclosure 120a or each dielectric material 40 by laser marking. The mark may represent the product information about the semiconductor device 1a, such as a model number (or called product NO.). Also, the surface of the metal part 5 may be optionally tinned to improve electrical conductivity.

As shown in FIG. 14, the metal part 5 may be cut into separate lead frames 110a by a cutting process. The packaging enclosures 120a are bonded with respective lead frames 110a. The semiconductor device 1a including the lead frame 110a, the packaging enclosure 120a and the chip 20 can be fabricated by the method depicted in FIG. 9 through FIG. 14. Furthermore, during the cutting process, the metal part 5 is cut while the packaging enclosures 120a are not cut.

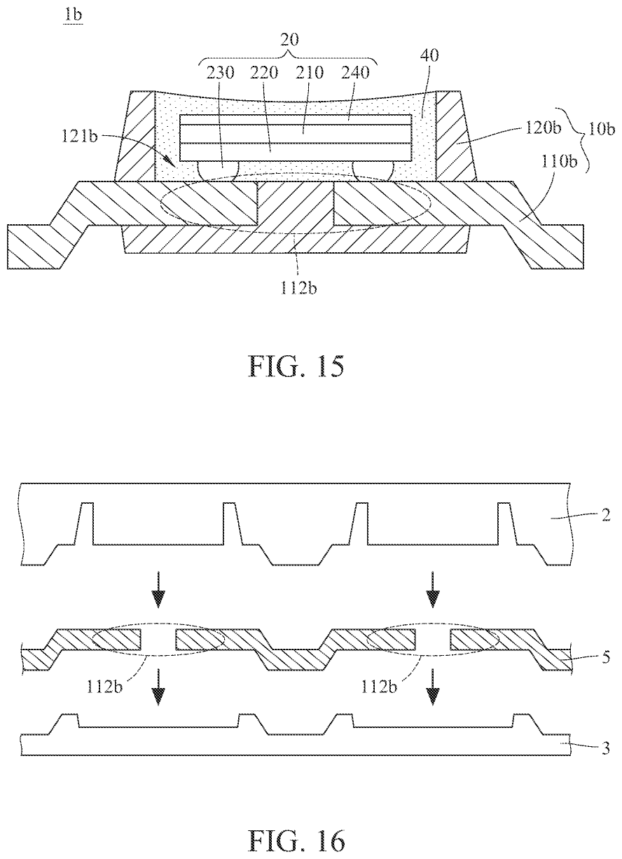

Another example of a semiconductor device where the chip 20 is packaged can be referred to FIG. 15. FIG. 15 is a schematic view of a semiconductor device according to a third embodiment of the present disclosure. In this embodiment, a semiconductor device 1b includes a pre-forming adaptor 10b, a chip 20 and a dielectric material 40. The semiconductor device 1b is, for example but not limited to, applied to servers, vehicle devices or high-end smartphones. The semiconductor device 1b may have different package outline from the semiconductor devices in FIG. 1 and FIG. 8.

The pre-forming adaptor 10b includes a lead frame 110b and a packaging enclosure 120b bonded with the lead frame 110b. The chip 20 is disposed in the pre-forming adaptor 10b, and the chip 20 is electrically connected to the lead frame 110b. A configuration of the chip 20 can be referred to the corresponding element in the first embodiment, and any detail description will be omitted hereafter. The dielectric material may be a polymer accommodated in a cavity 121b of the packaging enclosure 120b and encapsulate the chip 20.

FIG. 16 through FIG. 21 are schematic views showing a method of fabricating the semiconductor device in FIG. 15. First, the pre-forming adaptor 10b is provided by a pre-forming process.

The pre-forming process includes a step of providing multiple lead frames 110 having the pre-forming shape according to the package outline of the semiconductor device 1b. As shown in FIG. 16, a metal part 5 as single piece (that is, a one-pieced part) is bent to have a pre-forming shape. The metal part 5 may be cut into separate lead frames 110b with each having the pre-forming shape suitable as a pin in a subsequent step (as shown in FIG. 21), and the pre-forming shape of the metal part 5 may include multiple soldering patterns 112b corresponding to the distribution of solder balls on the chip.

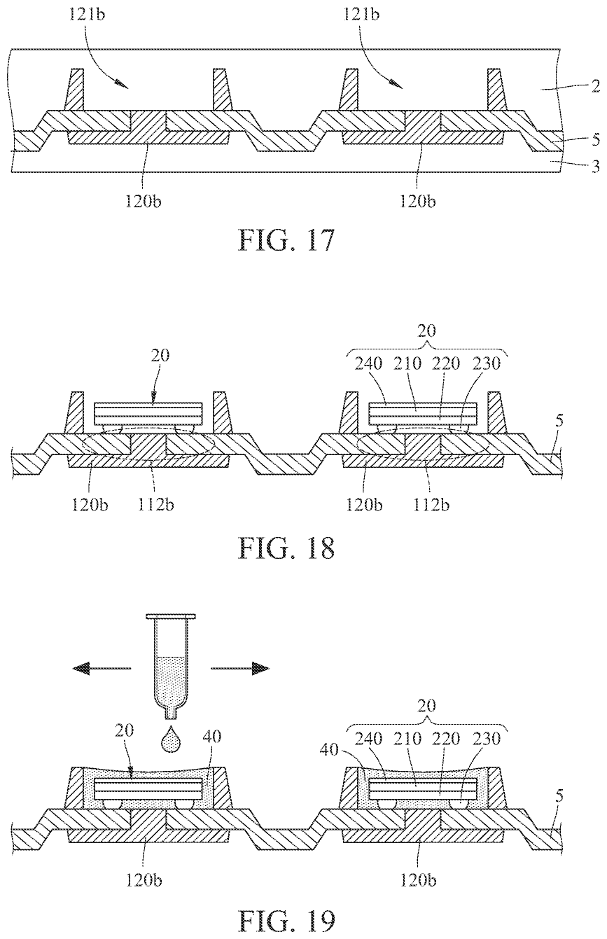

The pre-forming process further includes a step of forming multiple packaging enclosures 120b having the pre-forming shape on the metal part 5 by injection molding. As shown in FIG. 16 and FIG. 17, the metal part 5 is positioned between an upper mold 2 and a lower mold 3. The upper mold 2 and the lower mold 3 are in close contact with each other, and thermosetting dielectric material is injected into the molds to form separate packaging enclosures 120b. The outer surface of each of the packaging enclosures 120b may have a gate trace due to injection molding. After the injection molding, the packaging enclosures 120b are demolded to obtain the pre-forming adaptors 10b, and each of the packaging enclosures 120b includes a cavity 121b for accommodating the chip.

Next, multiple chips 20 are disposed in the pre-forming adaptors 10b. As shown in FIG. 18, the chips 20 are disposed in respective cavities 121b after the pre-forming process. The solder balls 230 of each of the chips 20 may be bonded with the soldering pattern 112b.

As shown in FIG. 19, liquid dielectric material 40 is filled into the cavity 121b of each packaging enclosure 120b. The dielectric material 40 solidifies so as to encapsulate the semiconductor layer 210, the redistribution layer 220 and the solder balls 230 of the chip 20. The dielectric material 40 in the cavity 121b can be optionally processed by post-mold cure.

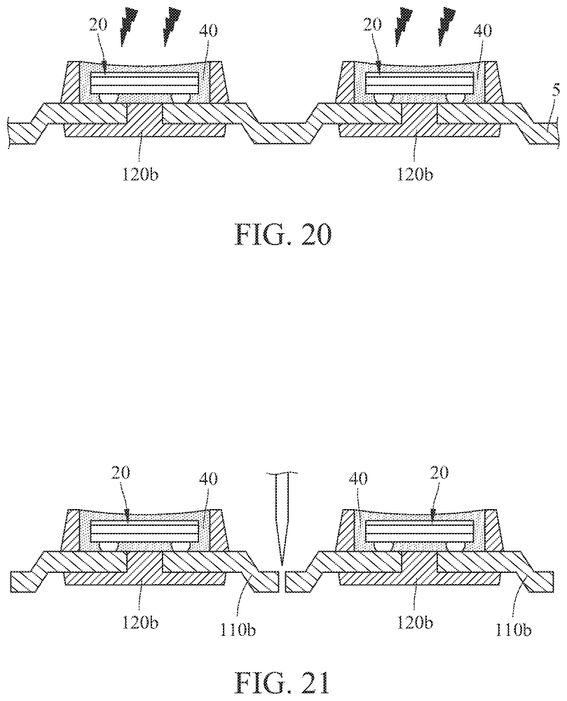

As shown in FIG. 20, a mark may be optionally formed on each packaging enclosure 12ba or each dielectric material 40 by laser marking. The mark may represent the product information about the semiconductor device 1b, such as a model number (or called product NO.). Also, the surface of the metal part 5 may be optionally tinned to improve electrical conductivity.

As shown in FIG. 21, the metal part 5 may be cut into separate lead frames 110b by a cutting process. The packaging enclosures 120b are bonded with respective lead frames 110b. The semiconductor device 1b including the lead frame 110b, the packaging enclosure 120b and the chip 20 can be fabricated by the method depicted in FIG. 16 through FIG. 21. Furthermore, during the cutting process, the metal part 5 is cut while the packaging enclosures 120b are not cut.

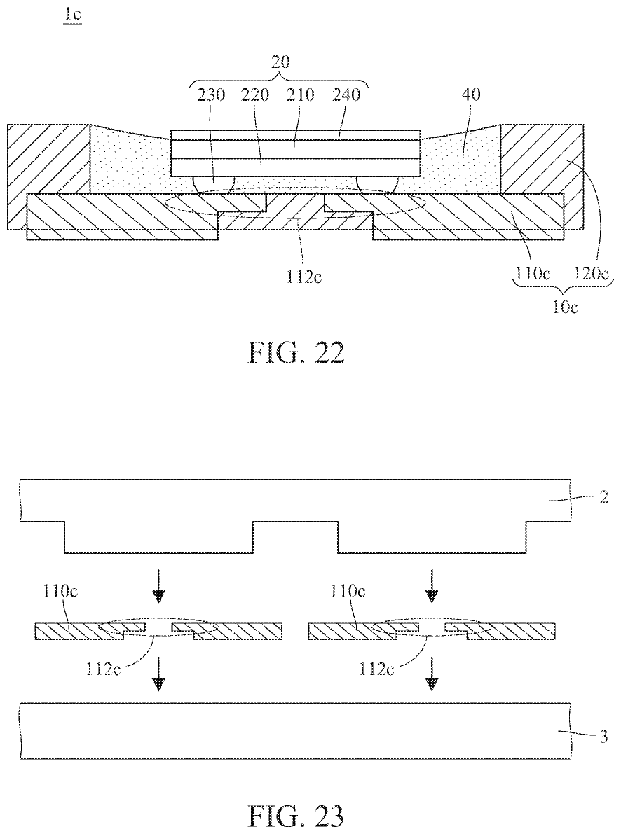

Still another example of a semiconductor device where the chip 20 is packaged can be referred to FIG. 22. FIG. 22 is a schematic view of a semiconductor device according to a fourth embodiment of the present disclosure. In this embodiment, a semiconductor device 1c includes a pre-forming adaptor 10c, a chip 20 and a dielectric material 40. The semiconductor device 1c is, for example but not limited to, applied to servers, vehicle devices or high-end smartphones. The semiconductor device 1c may have different package outline from the semiconductor devices in FIG. 1, FIG. 8 and FIG. 15.

The pre-forming adaptor 10c includes a lead frame 110c and a packaging enclosure 120c bonded with the lead frame 110c. The chip 20 is disposed to the pre-forming adaptor 10c, and the chip 20 is electrically connected to the lead frame 110c. Compared to the lead frames in FIG. 1, FIG. 8 and FIG. 15, the lead frame 110c in this embodiment may include flat leads without any bent portion. A configuration of the chip 20 can be referred to the corresponding element in the first embodiment, and any detail description will be omitted hereafter. The dielectric material 40 may be a polymer provided on a surface of the packaging enclosure 120c and encapsulate the redistribution layer 220 and the solder balls 230 of the chip 20.

FIG. 23 through FIG. 28 are schematic views showing a method of fabricating the semiconductor device in FIG. 22. First, the pre-forming adaptor 10c is provided by a pre-forming process.

The pre-forming process includes a step of providing multiple lead frames 110c having the pre-forming shape according to the package outline of the semiconductor device 1c. As shown in FIG. 23, a metal structure, such as a metal sheet with holes, may be pre-cut into separate lead frames 110c, and each of the lead frames 110c has flat top and bottom surfaces. The pre-forming shape of each lead frame 110c also includes a soldering pattern 112c corresponding to the distribution of solder balls on the chip.

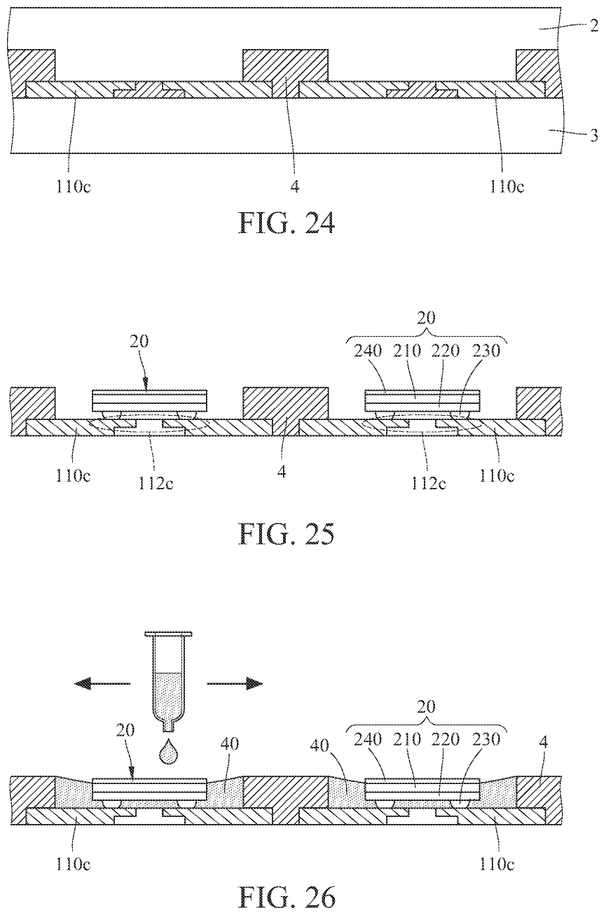

The pre-forming process further includes a step of forming multiple packaging enclosures 120c having the pre-forming shape on the lead frames 110c by injection molding. As shown in FIG. 23 and FIG. 24, the lead frames 110c are positioned between an upper mold 2 and a lower mold 3. The upper mold 2 and the lower mold 3 are in close contact with each other, and thermosetting dielectric material is injected into the molds to form an injection molded part 4 as single piece (that is, a one-pieced part). After the injection molding, the injection molded part 4 is demolded to obtain the pre-forming adaptors 10c. The injection molded part 4 may be cut into separate packaging enclosures 120c in a subsequent step (as shown in FIG. 28), and the injection molded part 4 may include multiple cavities 121c for accommodating chips.

Next, multiple chips 20 are disposed in the pre-forming adaptors 10c. As shown in FIG. 25, the chips 20 are disposed in respective cavities 121c after the pre-forming process. The solder balls 230 of each of the chips 20 may be bonded with the soldering pattern 112c, so that the chip 20 is electrically connected to the lead frame 110c.

As shown in FIG. 26, liquid dielectric material 40 is filled into the cavities 121c of the injection molded part 4. In one cavity 121c, the dielectric material 40 solidifies so as to encapsulate the redistribution layer 220 and the solder balls 230 of the chip 20. At least part of the semiconductor layer 210 of the chip 20 is not encapsulated by the dielectric material 40 so as to be exposed to outside. The dielectric material 40 in the cavity 121c can be optionally processed by post-mold cure.

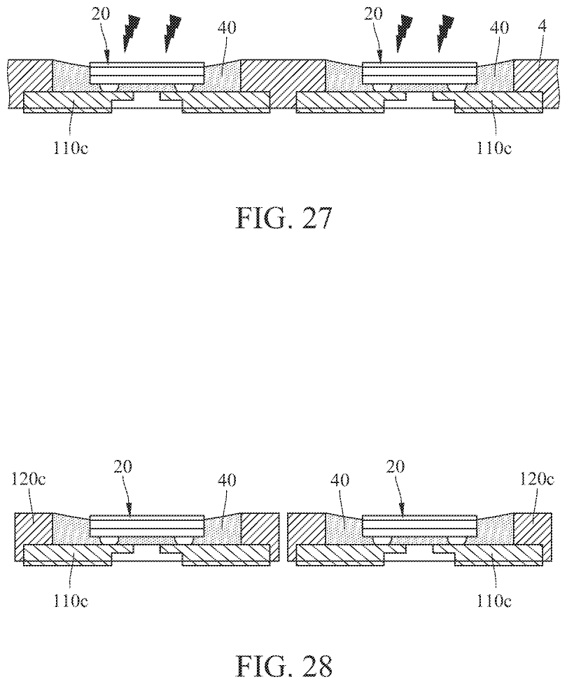

As shown in FIG. 27, a mark may be optionally formed on the injection molded part 4 or the dielectric material 40 by laser marking. The mark may represent the product information about the semiconductor device 1c, such as a model number (or called product NO.). Also, the surface of the lead frames 110c may be optionally tinned to improve electrical conductivity.

As shown in FIG. 28, the injection molded part 4 may be cut into separate packaging enclosures 120c by a cutting process. Each of the packaging enclosures 120c has one of the cavities 121c, and the packaging enclosures 120c are bonded with respective lead frames 110c. The semiconductor device 1c including the lead frame 110c, the packaging enclosure 120c and the chip 20 can be fabricated by the method depicted in FIG. 23 through FIG. 28. Furthermore, during the cutting process, the injection molded part 4 is cut while the lead frames 110c are not cut.

In the aforementioned embodiments, each of the cavities 121, 121a, 121b and 121c accommodates single chip 20, but the present disclosure is not limited thereto. In some other embodiments, depending on the requirements of end customers, multiple chips may be accommodated in each cavity.

According to the present disclosure, a pre-forming adaptor includes a lead frame and a packaging enclosure, and each of the lead frame and the packaging enclosure has a pre-forming shape provided according to a predetermined package outline of a semiconductor device. After the pre-forming adaptor is provided by a pre-forming process, the chip is packaged into the pre-forming adaptor to obtain the semiconductor device. Therefore, the pre-forming adaptor, which already have suitable outline required by, for example, a design house (one of the end customers), can be provided first, and then the chip is packaged into the pre-forming adaptor, so that it is helpful to reduce manufacturing cost and no need to redesign new package outline again. For example, in a condition that the end customers ask for the packaging of a chip, which is originally used in a semiconductor device with a primary model number consisting of some product specification features, into another semiconductor device with another model number consisting of some product specification features different from that of the primary model number, the assembly house only needs to change the pre-forming adaptors on a present assembly line, instead of setting up a new assembly line dedicated to the fabrication of said another semiconductor device with another model number.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A pre-forming adaptor for semiconductor packaging, comprising at least one lead frame and at least one packaging enclosure bonded with the at least one lead frame, wherein each of the at least one lead frame and the at least one packaging enclosure has a pre-forming shape provided according to a predetermined package outline of a semiconductor device.

2. The pre-forming adaptor for semiconductor packaging according to claim 1, wherein a number of the at least one lead frame is multiple, the lead frames are separate from one another, and the at least one packaging enclosure is an injection molded part as single piece.

3. The pre-forming adaptor for semiconductor packaging according to claim 1, wherein a number of the at least one packaging enclosure is multiple, the packaging enclosures are separate from one another, and the at least one lead frame is a metal part as single piece.

4. The pre-forming adaptor for semiconductor packaging according to claim 1, wherein the at least one packaging enclosure comprises a chip accommodation cavity.

5. A semiconductor device, comprising:
a pre-forming adaptor, comprising a lead frame and a packaging enclosure bonded with the lead frame, wherein each of the lead frame and the packaging enclosure has a pre-forming shape provided according to a predetermined package outline of the semiconductor device; and
a chip, disposed to the pre-forming adaptor, and the chip is electrically connected to the lead frame.

6. The semiconductor device according to claim 5, wherein the pre-forming shape of the lead frame comprises at least one bent portion.

7. The semiconductor device according to claim 5, wherein the pre-forming shape of the lead frame comprises a soldering pattern corresponding to at least one electrical connection point of the chip.

8. The semiconductor device according to claim 5, wherein the packaging enclosure is formed on the lead frame having the pre-forming shape by injection molding.

9. The semiconductor device according to claim 5, further comprising an under filler, wherein the chip and the under filler are accommodated in a cavity of the packaging enclosure, the chip comprises a semiconductor layer and an electrical connection point on the semiconductor layer, the electrical connection point is electrically connected to the lead frame, and the under filler encapsulates the electrical connection point and exposes at least part of the semiconductor layer.

10. The semiconductor device according to claim 5, further comprising a dielectric material, wherein the chip and the dielectric material are accommodated in a cavity of the packaging enclosure, and the dielectric material encapsulates the chip.
